(19) United States
(12) Patent Application Publication
(10) Pub. No.: US 2026/0131405 A1
(43) Pub. Date: May 14, 2026

(54) OXIDATION RESISTANT COPPER DIE-BONDING MATERIAL FOR METAL JOINING IN SEMICONDUCTOR DEVICES

(71) Applicant: Nano and Advanced Materials Institute Limited, Hong Kong (HK)

(72) Inventors: Ka I LEE, Hong Kong (HK); Ka Wah HAU, Hong Kong (HK); Yanhui WANG, Hong Kong (HK); Chin Ho LAM, Hong Kong (HK); Chi Ho KWOK, Hong Kong (HK); Yuechen WANG, Hong Kong (HK); Li FU, Hong Kong (HK)

(21) Appl. No.: 19/386,238

(22) Filed: Nov. 12, 2025

Related U.S. Application Data
(60) Provisional application No. 63/720,150, filed on Nov. 13, 2024.

(51) Int. Cl. B23K 35/30; B23K 35/02; B23K 101/40; H10W 72/00; H10W 72/30

(52) U.S. Cl. CPC B23K 35/302; B23K 35/025; H10W 72/07336; H10W 72/352; B23K 2101/40

(57) ABSTRACT

A copper die-bonding material for third-generation semiconductor device packaging. The bond is made from an oxidation-resistant copper paste engineered to minimize oxidation and optimize copper sintering density. As a result, dense bonds with high shear strength are formed. The oxidation-resistant copper paste includes copper metal particles and copper nanoparticles, wherein the copper nanoparticles are specifically engineered to have bimodal size distribution. The present invention provides a one-pot composition, which is directly applicable to a metallic substrate to initiate an oxidation-free sintering process, while providing enhanced shear strength and bond strength.

### FIELD OF THE INVENTION

The present invention relates to die attachment compositions in general, and, more particularly to copper-based die attachment compositions that are protected from oxidation during sintering.

### BACKGROUND OF THE INVENTION

Conventional lead-based solders present significant issues when used to attach third-generation semiconductors, such as those based on silicon carbide (SIC) and gallium nitride (GaN), to electronic packages. These materials are designed for high-power and high-temperature applications, often operating at temperatures well above 300° C., whereas conventional solders, such as lead-based solders (e.g., eutectic Pb—Sn (lead-tin) alloy solders), typically have melting points around 183° C. Therefore, at elevated temperatures, lead-based solders may soften or melt, causing mechanical instability, loss of electrical contact, or even device failure.

Further, SiC and GaN have high thermal conductivity and expansion properties. Lead-based solders do not match the thermal expansion coefficients of these materials, leading to thermal stresses. Over time, repeated thermal cycling (heating and cooling) can cause the solder joints to crack or degrade, reducing the reliability of the device.

Additionally, lead-based solders are also problematic from an environmental and regulatory standpoint. Regulations such as the European Union's RoHS (Restriction of Hazardous Substances) directive restrict the use of lead due to its toxicity, pushing the electronics industry to adopt lead-free alternatives.

To address these issues, several alternative bonding agents and techniques have been used in third-generation semiconductor circuitry joining.

Silver-based pastes: Silver-based materials may be used as an alternative to conventional solders. Silver-pastes, particularly those using micron or nano-sized particles, sinter at a relatively low temperature. For example, nano-silver pastes sinter at approximately 150-250° C. but form a stable high-temperature bond. This sintered bond exhibits a higher melting point, in the order of 960° C., the melting point for silver. Silver also possesses excellent thermal conductivity and high electrical conductivity. This makes it suitable for high-temperature and high-power applications. It also has good mechanical properties, minimizing the issues related to thermal expansion mismatch. Silver pastes are high in cost, however, limiting their applications.

Gold-Tin (AuSn) Solders: Gold-tin alloys (AuSn) are often used for high-temperature semiconductor applications. AuSn solder has a melting point around 280° C., making it more suitable for joining SiC and GaN devices that operate at higher temperatures. AuSn also offers good electrical conductivity and thermal stability. However, gold-tin alloys are expensive also.

Transient Liquid Phase Bonding (TLP): TLP involves the use of a low-melting-point alloy that forms a high-melting-point intermetallic compound at the bonding interface during heating. This technique produces stable bonds that can withstand higher temperatures once the intermetallic phases are formed. TLP is advantageous for high-temperature and power electronics applications. However, despite a relatively lower bonding temperature than traditional diffusion bonding, TLP still requires a high bonding temperature (typically 60-80% of the melting point of the base metal). In addition, taking into consideration that the diffusion of the melting-point depressant (MPD) from the liquid interlayer into the base materials, the bonding may require extended holding times at elevated temperatures, coupled with the requirement of vacuum furnaces or controlled-atmosphere chambers, the process is still energy-intensive and considerably costly.

Conductive Epoxies: While not as conductive as metallic solders, conductive epoxies are sometimes used in less demanding applications. They can handle higher operating temperatures and provide a flexible bond, reducing stress on the semiconductor. However, they generally have lower thermal and electrical conductivity compared to metallic bonds.

Although these alternatives exhibit sufficient reliability in third-generation semiconductor device joining under high-temperature operating environments, they are generally expensive (silver and gold) or have inadequate thermal and electrical conductivity (epoxies).

The state of the art has turned to copper particle-based pastes for bonding SiC and GaN components to join microelectronic components due to their excellent electrical conductivity and cost-effectiveness. However, copper tends to oxidize rapidly when exposed to air, especially at the nanoscale. To address these challenges and optimize the performance of copper pastes, various additives and strategies have been employed.

In particular, various metallic complexes have been added to improve the oxidation resistance of copper particles. For example, adding small amounts of silver complexes can improve the oxidation resistance of copper. The silver forms an alloy with copper, which stabilizes the surface and reduces oxidation. Similarly, palladium complexes can be added in very small amounts to enhance copper oxidation resistance by forming a stable Pd—Cu alloy layer that prevents surface oxidation.

Approaches using additional metal complexes may prevent oxidation but greatly increase the expense of the copper-based pastes. Thus, there is a need in the art for improved copper-based pastes that exhibit reduced oxidation in a sintering environment. Such copper pastes could be used for joining high-temperature semiconductors, such as SiC and GaN devices, to microelectronic packages and circuitries. The present invention addresses this need.

### SUMMARY OF THE INVENTION

In addressing the aforementioned need in the current state of the art, one aspect of the present invention provides an oxidation-resistant copper die-bonding material for third-generation semiconductor device packaging. The die-bonding material is made from an oxidation-resistant copper paste and is formed under conditions that result in minimal oxidation and high density. As a result, dense bonds with high shear strength are formed. The oxidation-resistant copper paste includes copper metal particles and uncapped copper nanoparticles. The solvent is configured to produce a reductive environment, achieving an oxidation free sintering process.

The composition of the copper paste includes 10-60 wt % copper metal particles and 30-80 wt % copper nanoparticles. The copper paste further includes 10-20 wt % solvents and 0.1-5 wt % additives so that the paste has a selected rheology to enable its use in existing automated packaging equipment.

In one embodiment, the copper metal particles include flake-shaped copper particles, spherical-shaped copper particles, plate-shaped copper particles, or combinations thereof. The copper nanoparticles are subdivided into two groups, wherein the first group comprises copper nanoparticles of particle sizes in a range of 10-80 nm and having crystallite sizes in a range of 15-40 nm, and the second group comprises copper nanoparticles of particle sizes in a range of 100-200 nm and having crystallite sizes in a range of 90-130 nm. The solvent is configured to comprise both amino and hydroxyl functional groups as anti-agglomeration agent and reducing agent for preventing oxidation of copper nanoparticles.

In an embodiment of the present invention, the copper metal particles have particle sizes in a range of 0.3 to 10 μm.

In another embodiment, the copper metal particles are copper metal flakes with an aspect ratio of 2 or greater.

In another embodiment, the copper metal particle sizes are in a range of 1 to 3 μm.

In yet another embodiment, the solvent for the copper paste is selected from ethylene glycol, diethylene glycol, triethylene glycol, tetraethylene glycol, 1,3-butylene glycol, dipropylene glycol methyl ether acetate, dipropylene glycol monobutyl ether, dipropylene glycol, diethylene glycol monobutyl ether acetate, triacetin, terpineol, triethanolamine, monoethanolamine, monoisopropanolamine, 2-amino-2-methyl-1-propanol, diglycolamine, diethanolamine, N-methylethanolamine, diisopropanolamine, 2-(tert-butylamino) ethanol, methyldiethanolamine, N-butyldiethanolamine, dimethylethanolamine, triisopropanolamine, diethylethanolamine, or combinations thereof.

In yet another embodiment, the additive is selected from the group comprising polyether modified dimethylpolysiloxane copolymer, a polyamide-based rheology modifier, or a modified urea-based rheology modifier, hexanoic acid, citric acid, malonic acid, ascorbic acid, 3-glycidoxypropyltrimethoxysilane, or a combination thereof.

In accordance with another aspect of the present invention, a two-step sintering method using the aforementioned oxidation-resistant microelectronic joining paste is provided. The method comprises applying the aforementioned copper paste to a substrate, placing a microelectronic component at least partially on the copper paste applied to the substrate, and heating to a temperature in a range of 250° C. to 280° C. to sinter the copper metal particles with nanoparticles from copper salt and bond the microelectronic component to the substrate.

In one embodiment, the substrate is selected from copper finishing, silver finishing, gold finishing, platinum finishing or nickel finishing.

In other embodiment, the microelectronic component or die is selected from copper finishing, silver finishing or gold finishing.

In yet another embodiment, the bondline thickness between the copper metal particles and the copper nanoparticles is 30-50 μm.

In yet other embodiment, the porosity of the paste after sintering is no higher than 10%.

In yet another embodiment, the sintering is conducted under nitrogen environment and either (i) under a pressure of 1 atm for a time period of approximately 60-90 minutes; or (ii) under a pressure of 10-25 MPa for a time period of approximately 10 minutes.

In a further embodiment, the shear strength of the bond when sintering is conducted in condition (i) above is no lower than 30 MPa; and the shear strength of the bond when sintering is conducted in condition (ii) above is no lower than 50 MPa.

### BRIEF DESCRIPTION OF THE DRAWINGS

Embodiments of the invention are described in more details hereinafter with reference to the drawings, in which:

FIGS. 1A to 1C show scanning electron microscopy (SEM) images of copper nanoparticles synthesized with the exemplary procedures described below. FIG. 1A shows the SEM image of copper nanoparticles synthesized under synthesis route 1; FIG. 1B shows the SEM image of copper nanoparticles synthesized under synthesis route 2 and FIG. 1C shows the SEM image of copper nanoparticles synthesized under synthesis route 3 as described in detail in the below section.

FIGS. 2A and 2B show SEM images of exemplary copper microelectronic joining pastes of the present invention, highlighting their low post-sintering porosity. FIG. 2A shows the SEM image of copper microelectronic joining paste after pressure-assisted sintering. FIG. 2B shows the SEM image of copper microelectronic joining paste after pressureless sintering.

FIG. 3 shows the X-ray diffraction (XRD) spectrum of the copper nanoparticles in an exemplary microelectronic joining paste embodiment.

FIG. 4 shows the XRD spectrum of the copper metal particle.

### DETAILED DESCRIPTION

In accordance to the embodiments of the present invention, the oxidation-resistant copper die-bonding material is made from an oxidation-resistant copper paste that includes four categories of ingredients: 1. copper metal particles in 10-60 wt %; 2. copper nanoparticles in 30-80 wt %; 3. solvent in 10-20 wt %; and 4. additives in 0.1-5 wt %. Each of these ingredient categories is discussed in detail below. Following the description of the ingredient categories is a description of the sintering conditions for joining third-generation semiconductors to microelectronic packages and circuitries. Examples describe particular compositions and tests on the sintered bonds formed.

### 1. Copper Metal Particles

Copper metal particles constitute 70-85 wt % of the copper paste. In order to form dense bonds that will possess high shear strength and good electrical and thermal conductivity, the particle size and shape must be carefully selected in order to insure the highest amount of particle packing density.

The packing density, as used herein, refers to how efficiently the copper particles can fill the available volume in the paste. The higher the packing density, the greater the contact area between particles, leading to a denser final bond after sintering. Different particle shapes offer varying degrees of efficiency when it comes to packing and sintering. For example, spherical particles typically have a lower packing density compared to other shapes due to the way they naturally form loose-packed structures (e.g., face-centered cubic or hexagonal close-packed arrangements). Spheres cannot efficiently fill all the gaps between them. The ideal packing density for spheres is around 64%, meaning 36% of the volume is voids. This leaves more space that needs to be filled during the sintering process. However, although spherical particles have a low packing density, they have high surface area-to-volume ratios at the points where they touch, which promotes sintering at the contact points. However, because of the higher number of voids between them, the particles need to undergo significant diffusion during sintering to eliminate the gaps, often requiring higher sintering temperatures to achieve full densification.

In contrast to spherical particles, flakes or plate-like particles tend to have higher packing densities than spheres because their flat surfaces can stack or overlap, allowing for less wasted space between particles. Further, the large surface area of contact between the flake-shaped particles improves the physical interaction between them, promoting better bonding during sintering. As a result, higher bond density may be formed which can result in higher electrical and thermal conductivity bonds. Flakes require a lower sintering temperatures since flakes can reduce the amount of diffusion required during sintering since they have larger contact areas. However, if all of the selected particles are flake-shaped particles; the formed bond may be highly anisotropic properties, with the bond strength or electrical conductivity being substantially stronger in the direction parallel to the semiconductor and substrate.

Because small particles, for example, those under 10 microns, and nanoparticles have an extremely high surface area to volume ratio, diffusion is rapidly accelerated during sintering. Further, nano-sized particles may be used to fill voids between larger particles, increasing the bond density of the sintered bond.

Due to the above characteristics, the present invention determined that a mixture of flake-shaped particles and spherical particles promotes high bond density as well as reducing agglomeration of the copper paste, ensuring good paste rheology and processability. The present invention also determined that a particle size distribution employing a mixture of particle shapes and sizes produces the highest bond strength and bond density. For example, flakes may offer high packing density, while smaller spherical particles can fill remaining voids. Smaller particles (such as nanoparticles) fill the voids between larger particles (e.g., spheres or flakes).

In one embodiment, the copper metal particles are flake shaped copper particles having particle sizes in a range of 1-10 μm and an aspect ratio of 2 or greater; or spherical shaped sub-micron or nano copper particles having particle sizes in a range of 0.3-1.5 μm; having crystallite sizes in a range of 15-40 nm. The copper metal particles may be flake-shaped particles, spherical copper particles, or a combination of both. Optionally the copper metal particle mixture may include other shapes or solely some other shape depending on the desired applications.

The sub-40 nm crystallite size of the inventive copper material is critical for low-temperature sintering. This nanostructure creates a high density of grain boundaries, which substantially increases the thermodynamic driving force for densification while providing rapid atomic diffusion pathways. Consequently, the material achieves complete densification and forms robust interparticle necks at significantly reduced temperatures and shorter durations compared to conventional copper.

This carefully controlled copper metal particle mixture creates a more uniform structure, reduces voids, and increases packing density, ultimately lowering the sintering temperature because fewer gaps need to be filled during sintering.

### 2. Copper Nanoparticles

Copper nanoparticles are used to fill in voids and increase packing density which lowering the sintering temperature and reducing porosity in the final copper bond.

Specifically, the copper nanoparticles in accordance with the various embodiments of the present invention are engineered to be subdivided into two groups with distinct particle sizes, with a first group of copper nanoparticles having particle sizes in a range of 10-80 nm with crystallite sizes in a range of 15-40 nm, and a second group of copper nanoparticles having particle sizes in a range of 100-200 nm with crystallite sizes in a range of 90-130 nm. This bimodal mixture optimizes packing density and conductivity enhancement.

Upon deposition of the copper paste onto a metallic substrate, the smaller copper nanoparticles of the first group fill in the interstitial void between larger copper nanoparticles in the second group, thus forming a densely packed particle network. In particular, comparing to existing sintering pastes, which usually adopt copper nanoparticles with sizes spanning a continuous size spectrum that do not facilitate the “void-filling” packing structure, the packing structure having the bimodal configuration of the present invention minimizes void volume and ensures particle-to-particle contact throughout the paste layer prior to sintering.

As heat is applied in the thermal treatment, as smaller nanoparticles generally have lower sintering onset temperature, neck formation is initiated at relatively lower temperatures, which in turn bridges the neighboring larger nanoparticles to promote localized densification.

As sintering temperature increases, diffusion pathways propagate from the smaller nanoparticles to the larger nanoparticles, resulting in progressive metallurgical bonding. The bimodal configuration thereby facilitates a staged sintering process which combines the rapid diffusion kinetics of the smaller nanoparticles with the electrical continuity and mechanical robustness of the large nanoparticles, granting the sintered copper layer a high bulk density, low residual porosity and enhanced electrical conductivity to the underlying substrate, and also increased adhesion to the underlying substrate, as shown in an increase in shear strength and a reduction in bondline thickness.

### 3. Solvents

The solvent selection affects the copper paste's viscosity, printability, drying characteristics, and the sintering behavior of copper particles. In copper pastes, the solvents serve to dissolve or disperse the copper precursor complexes, binders, and additives to ensure smooth and uniform deposition during the application process. Additionally, the solvents may evaporate at various stages of the sintering process, influencing the drying speed, particle alignment, and overall quality of the final bond. By remaining in the paste during early stages of sintering, solvents help copper particles distribute evenly before fully evaporating. This contributes to the formation of dense, defect-free copper bonds at lower sintering temperatures. Generally, selecting solvents for particular applications depends on the type of application technique for joining microelectronics.

In one embodiment of the present invention, particular solvents include ethylene glycol, diethylene glycol, triethylene glycol, tetraethylene glycol, 1,3-butylene glycol, dipropylene glycol methyl ether acetate, dipropylene glycol monobutyl ether, dipropylene glycol, diethylene glycol monobutyl ether acetate, triacetin, terpinol, triethanolamine, monoethanolamine, monoisopropanolamine, 2-amino-2-methyl-1-propanol, diglycolamine, diethanolamine, N-methylethanolamine, diisopropanolamine, 2-(tert-butylamino) ethanol, methyldiethanolamine, N-butyldiethanolamine, dimethylethanolamine, triisopropanolamine, diethylethanolamine, or combinations thereof. Mixtures of these solvents may also be used.

Terpineol is a cyclic monoterpene alcohol, often used in the form of α-terpineol. It is a viscous, oily liquid with a relatively high boiling point (˜219° C.). Terpineol can control the viscosity of the formulation since its relatively high viscosity allows the copper paste to be more stable and reduces the risk of sedimentation of copper particles during storage or processing. It can be useful for screen printing due to its rheological properties and slow evaporation rate due to its high boiling point.

Triethanolamine (TEA) is a tertiary amine and triol, which makes it both a solvent and a complexing agent. It has a boiling point of ˜335° C., making it a high-boiling solvent. TEA may act as a chelating agent for copper ions, stabilizing the copper precursor complexes, such as copper formate or acetate, and preventing premature reduction or aggregation of copper particles. This stabilizing effect can extend the shelf life of the copper paste. TEA can also act as a mild base, providing a reducing environment during the sintering process. By stabilizing the copper ions, it mitigates oxidation, preventing the formation of copper oxides during the decomposition of the precursor. TEA may also improve the wetting properties of the paste on substrates, which ensures good adhesion and uniform distribution of copper particles before sintering.

Tetraethylene Glycol (TEG) is a linear ether with four ethylene glycol units, giving it a relatively high boiling point (˜330° C.) and a moderate viscosity. As such it may facilitate better particle alignment and distribution before the solvent evaporates. TEG may also function as a plasticizer, softening the binder matrix during the drying and sintering processes. This reduces the risk of cracking or shrinkage in the paste.

Diethylene Glycol (DEG) is a short-chain polyether diol with a boiling point of approximately 245° C. Similar to TEG above, DEG may serve as a co-solvent to aid copper nanoparticle dispersion while maintaining reductivity via hydroxyl groups for providing oxidation resistance to the copper nanoparticles.

Triethylene Glycol (TriEG) is a linear ether with three ethylene glycol units. It has a boiling point between TEG and DEG (˜285° C.), and is characterized by its strong solvation of metal ions and nanoparticles. It has a relatively high thermal stability to act as a stabilizing medium to the paste besides its reductive properties through the hydroxyl groups, and also improves film uniformity upon drying.

1,3-Butylene Glycol (1,3-BG) is a diol with primary and secondary hydroxyl groups. While its boiling point of ˜205° C. is relatively lower than other species with mildly reducing properties, it provides improved dispersion of copper nanoparticles to provide enhancement in wetting and adhesion of the paste onto various metallic substrates.

Diethylene Glycol Monobutyl Ether Acetate (DGBEA) is an esterified glycol ether with a relatively high boiling point (˜230° C.) and moderate volatility. DGBEA improves the wetting and spreading of the copper paste on various substrates, enhancing adhesion and uniform deposition.

Dipropylene Glycol Monobutyl Ether (DPnB) is a glycol ether with moderate volatility and a boiling point of ˜230° C. DPnB may be used in copper pastes to adjust the viscosity and rheology of the formulation. Its moderate volatility ensures that it remains in the paste long enough to promote smooth deposition and flow during the printing or dispensing process. DPnB can also dissolve various additives used in copper pastes, such as dispersants, stabilizers, and binders, ensuring that all components are uniformly distributed within the paste.

Dipropylene Glycol Methyl Ether Acetate (DPGMEA) is an ether-ester mixed-isomeric solvent. With a boiling point of ˜190° C. and moderate polarity, DPGMEA provides good solvency for organic and resins, and excellent dispersion properties for uniform film formation. As such, DPGMEA is a good agent to fine-tune drying behavior and film smoothness.

Dipropylene Glycol (DPG), a branched diol with boiling point of ˜230° C., it provides hydroxyl functionality for maintaining a reducing environment and stabilizing the copper nanoparticles through hydrogen bonding. The branched structure in particular improves dispersion uniformity and reduces aggregation.

Triacetin, also known as Glycerol Triacetate, is a triester of glycerol and acetic acid with a boiling of ˜260° C. While it lacks free hydroxyl, it provides viscosity and plasticizing properties to control solvent evaporation and mechanical flexibility of the deposited layer to improve post-sintering integrity of the film.

In addition to the above, some other feasible solvent options for the microelectronic copper sintering paste include, but are not limited to: monoethanolamine, monoisopropanolamine, 2-amino-2-methyl-1-propanol, diglycolamine, diethanolamine, N-methylethanolamine, diisopropanolamine, 2-(tert-butylamino) ethanol, methyldiethanolamine, N-butyldiethanolamine, dimethylethanolamine, triisopropanolamine, diethylethanolamine.

These solvents are primary, secondary, and tertiary amines with hydroxyl groups. The existence of —NH₂, —N—, —OH— and/or —O— groups provide general protection to the copper nanoparticles against oxidation, while having good balances between rheological properties and overall thermal and chemical stability.

### 4. Additives

The additives for the copper paste include additional reducing agents, optional rheology control agents, and optional sintering aids.

Reducing agents include acids such as ascorbic acid, citric acid, and other organic acids. These can assist in preventing oxidation, maintaining the copper metal particles and copper nanoparticles in their metallic state, or removing any formed surface oxides.

Rheology control agents include various trade-named products: WA7333, BYK®-331, BYK®-333, BYK®-440, RHEOBYK®-7410ET, and RHEOBYK®-440; or combinations thereof. BYK®-331 is a polyether modified dimethylpolysiloxane copolymer that acts as a silicone-based surface additive for solvent-borne, aqueous, and UV-curable systems. BYK®-333 by BYK® is a polyether modified polydimethylsiloxane that acts as a surface additive and provides strong reduction of surface tension and can assist in substrate wetting. RHEOBYK®-7410 ET/BYK®440 by BYKR is a modified urea-based liquid rheology additive to generate highly thixotropic flow behavior for medium-polarity solvent-borne and solvent-free systems. RHEOBYK®-440 is a polyamide-based rheology modifier.

The sintering aids include fluxing agents that aid to remove any oxides formed on copper during the sintering process, thus increasing the bond density.

In addition to carefully controlling the copper paste composition, another aspect of the present invention provides a two-step method for sintering the oxidation-resistant microelectronic joining material. In particular, the present invention simply requires application of the material onto a metallic substrate, and heating to a temperature under nitrogen environment in a range of 260° C. to 280° C. to sinter the copper metal particles with copper nanoparticles, and bond the microelectronic component to the substrate. This two-step method is applicable to the bonding of microelectronic components to a wide range of metallic substrates including copper finishing, silver finishing, gold finishing, platinum finishing or nickel finishing.

Nitrogen is a cost-effective inert gas in reducing the risk of oxidation and also having low environmental impact as it can be exhausted directly to the atmosphere. Optionally, a small amount of hydrogen (on the order of 5 to 10 percent H₂) may be added. The combination of nitrogen and hydrogen is sometimes called “forming gas” and is commercially available.

To ensure a good bond density, the present invention may use pressure-based sintering. By applying external pressure during the heating process, particle contact and bonding and enhanced. The pressure helps promote densification by driving the copper particles into closer contact, reducing porosity, and improving the diffusion process. Pressure allows sintering to occur at lower temperatures than would be required for pressureless sintering, which is beneficial for temperature-sensitive components. Further, the bonds formed by pressure-based sintering tend to have better mechanical strength due to improved densification.

Accordingly, the above sintering method can be conducted either (i) under a pressure of 1 atm for a time period of approximately 90 minutes; or (ii) under a pressure of 10-25 MPa for a time period of approximately 10 minutes. Both scenarios require the same bonding temperature as mentioned above, i.e. 260° C. to 280° C.

With the carefully engineered oxidation-resistant microelectronic joining paste and the simple two-step sintering method, the bond created under pressureless sintering has a shear strength of at least 30 MPa, while the bond created under pressure-assisted sintering has a shear strength of at least 50 MPa, highlighting the mechanical robustness of the sintered joint.

Moreover, the bondline thickness between the copper metal particles and the copper nanoparticles is also maintained at a minimal level of under 30 μm, which is essential in minimizing the thickness of the bonded layer to ensure optimal thermal and electrical conductivity.

### EXAMPLES

### Example 1: Synthesis of Copper Nanoparticles

### Nanoparticle Synthesis Route 1:

A 2 L round-bottom flask equipped with a magnetic stirrer is prepared. Into the flask, 94.2 g of copper acetate monohydrate is charged as a copper source. Then, 60 g of water and 425 g of isopropanol as an organic solvent are further added to the flask to obtain a reaction solution.

The liquid temperature of the reaction solution is raised to 62° C. while stirring mechanically at 1000 rpm. Under continued stirring, 11.82 g of 55% hydrazine monohydrate is added to the reaction solution at a rate of 1.6 mL/min using a syringe pump. The reaction solution is then stirred for 30 minutes. Thereafter, 106.4 g of 55% hydrazine monohydrate is added to the reaction solution at a rate of 3.2 mL/min using a syringe pump. The reaction solution is further stirred for 15 minutes. Subsequently, 47.3 g of 55% hydrazine monohydrate is added to the reaction solution at a rate of 3.2 mL/min using a syringe pump. Afterward, the reaction solution is maintained at 60° C. and stirred for 1.5 hours.

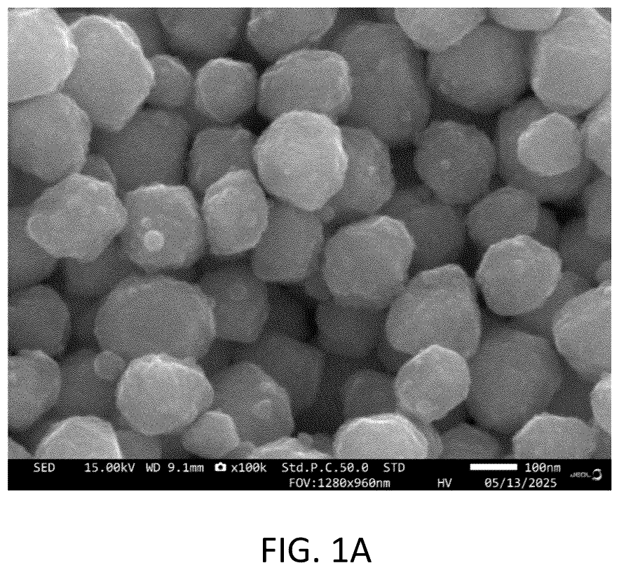

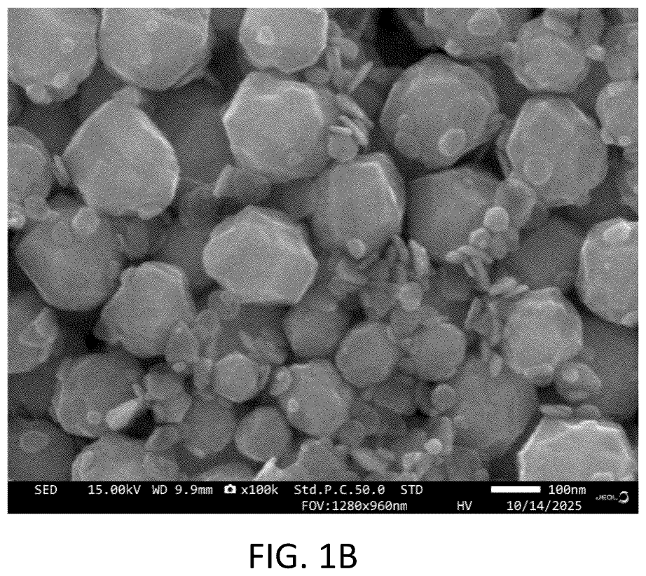

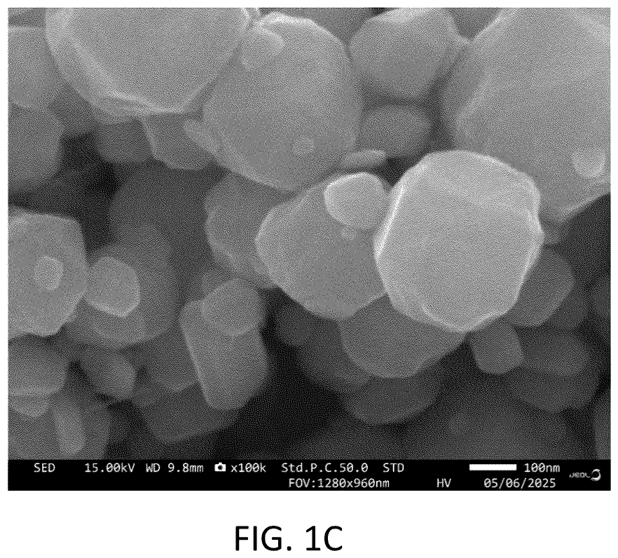

FIG. 1A shows the SEM image of resulting copper nanoparticles.

### Nanoparticle Synthesis Route 2:

A 250 mL round-bottom flask equipped with a magnetic stirrer is prepared. Into the flask, 47.1 g of copper acetate monohydrate is charged as a copper source. Then, 30 g of water and 220 g of isopropanol as an organic solvent are further added to the flask to obtain a reaction solution.

The liquid temperature of the reaction solution is raised to 60° C. while stirring mechanically at 380 rpm. Under continued stirring, 5.91 g of 55% hydrazine monohydrate is added to the reaction solution at a rate of 3.2 mL/min using a syringe pump. The reaction solution is then stirred for 30 minutes. Thereafter, 47.2 g of 55% hydrazine monohydrate is added to the reaction solution at a rate of 3.2 mL/min using a syringe pump. The reaction solution is further stirred for 15 minutes. Subsequently, 6.0 g of 55% hydrazine monohydrate is added to the reaction solution at a rate of 3.2 mL/min using a syringe pump. Afterward, the reaction solution is maintained at 60° C. and stirred for 1.5 hours.

After the reaction was completed, the reaction solution is cooled in an ice-water bath for 1 hour, followed by centrifugation (8000 rpm, 20 minutes). The obtained solid component is washed three times with ethanol, yielding approximately 14 g (87%) of the copper nanoparticles.

Please refer to FIG. 1B for the SEM image of the resulting copper nanoparticles.

### Nanoparticle Synthesis Route 3:

A 250 mL round-bottom flask equipped with a magnetic stirrer is prepared. Into the flask, 47.1 g of copper acetate monohydrate is charged as a copper source. Then, 30 g of water and 220 g of isopropanol as an organic solvent are further added to the flask to obtain a reaction solution.

The liquid temperature of the reaction solution is raised to 90° C. while subjected to magnetic stirring at 380 rpm. Under continued stirring, 5.91 g of 55% hydrazine monohydrate is added to the reaction solution using a dropping funnel. The reaction solution is then stirred for 30 minutes. Thereafter, 47.2 g of 55% hydrazine monohydrate is added to the reaction solution at a rate of 3.2 mL/min using a syringe pump. The reaction solution is further stirred for 15 minutes. Subsequently, 6.0 g of 55% hydrazine monohydrate is added to the reaction solution at a rate of 3.2 mL/min using a syringe pump. Afterward, the reaction solution is maintained at 90° C. and stirred for 1.5 hours.

After the reaction was completed, the reaction solution is cooled in an ice-water bath for 1 hour, followed by centrifugation (8000 rpm, 20 minutes). The obtained solid component is washed three times with ethanol, yielding approximately 14 g (87%) of the copper nanoparticles.

FIG. 1C shows the SEM image of the synthesized copper nanoparticles.

### Example 2: Synthesis of Microelectronic Joint Paste

### Synthesis and Sintering Route 1:

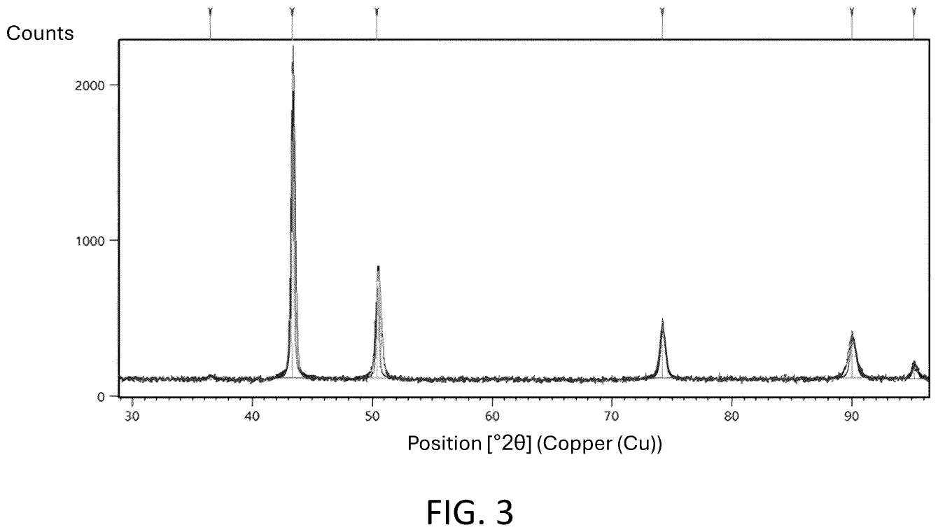

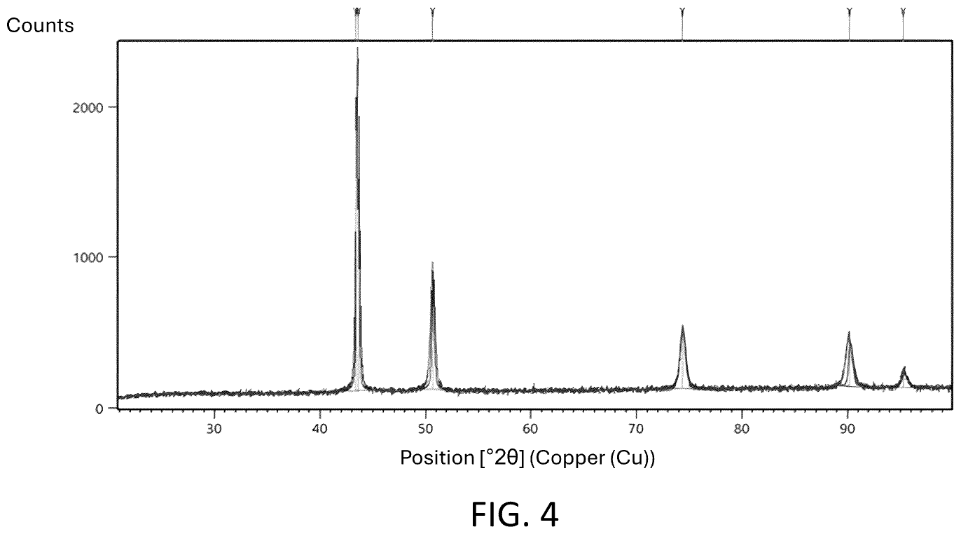

Mix the copper nanoparticles (synthesized with procedures as elaborated in Example 1 above, the XRD spectrum of these copper nanoparticles is shown in FIG. 3), flake-shaped copper metal particles in size range of 1-6 μm, triethanolamine and ethylene glycol in 10-60 wt %, 20-60 wt %, 3-10 wt % and 10-25 wt % respectively to obtain the copper paste.

For sintering, first clean the copper AMB substrate in 2% citric acid for 5-10 sec, wash with deionized water and ethanol, and dry a low temperature. Then, the copper paste is applied onto the copper AMB substrate by stencil printing. Place the copper AMB substrate in oven at 120° C. for 10 mins under air as a pre-curing process. Then, place the 3 mm*3 mm silver coated SiC die onto the copper paste and conduct die bonding at room temperature for 10 sec at 5-8 kg. Finally, the copper paste is sintered at 260° C. for 10 mins at 20 MPa under nitrogen atmosphere.

Table 1 below tabulates different samples with different copper nanoparticle-to-copper metal particles weight ratio, and their respective mechanical properties.

TABLE 1

| | | Flake | | | |
|---|---|---|---|---|---|
| | | copper | Shear | Shear | Shear |
| | Copper | metal | strength | strength | strength |
| | nanoparticles | particles | Average | Maximum | Minimum |
| Sample | (wt %) | (wt %) | (MPa) | (MPa) | (MPa) |
| CuP-F146 | 50-60 | 20-30 | >65.4 | 90.7 | >50.216 |
| CuP-F147 | 30-40 | 40-50 | 52.7 | 65.8 | 48.4 |
| CuP-F148 | 10-20 | 50-60 | 24.4 | 28.0 | 21.8 |

(Note: “>” indicates die failure.)

### Synthesis and Sintering Route 2:

Mix the copper nanoparticles (synthesized with procedures as elaborated in Example 1 above), spherical copper metal particles in size range of 0.5-3 μm, triethanolamine. ethylene glycol and malonic acid in 30-60 wt %, 20-50 wt %, 3-10 wt %, 5-10 wt % and 1-2 wt % respectively to obtain the copper paste.

For sintering, first clean the copper AMB substrate in 2% citric acid for 5-10 sec, wash with deionized water and ethanol, and dry a low temperature. Then, the copper paste is applied onto the copper AMB substrate by stencil printing. Place the copper AMB substrate in oven at 120° C. for 10 mins under air as a pre-curing process. Then, place the 3 mm*3 mm silver coated SiC die onto the copper paste and conduct die bonding at room temperature for 10 sec at 5-8 kg. Finally, the copper paste is sintered at 260° C. for 10 mins at 20 MPa under nitrogen atmosphere.

Table 2 below tabulates different samples with different copper nanoparticle-to-copper metal particles weight ratio, and their respective mechanical properties.

TABLE 2

| | | Spherical | | | |
|---|---|---|---|---|---|
| | | copper | Shear | Shear | Shear |
| | Copper | metal | strength | strength | strength |
| | nanoparticles | particles | Average | Maximum | Minimum |
| Sample | (wt %) | (wt %) | (MPa) | (MPa) | (MPa) |
| CuP-F149 | 50-60 | 20-30 | 51.2 | 71.7 | 35.0 |
| CuP-F150 | 30-40 | 40-50 | 65 | 75.8 | 55.5 |

### Comparative Example

This comparative example utilizes the same copper metal particles as Example 2 above, and serves as a comparison with Example 2.

For the synthesis of copper paste, mix the spherical copper metal particles in 0.5-3 μm, triethanolamine, ethylene glycol and malonic acid in 80-90 wt %, 3-10 wt %, 5-10 wt % and 1-2 wt % respectively to obtain the copper paste.

For sintering, first clean the copper AMB substrate in 2% citric acid for 5-10 sec, wash with deionized water and ethanol, and dry a low temperature. Then, the copper paste is applied onto the copper AMB substrate by stencil printing. Place the copper AMB substrate in oven at 120° C. for 10 mins under air as a pre-curing process. Then, place the 3 mm*3 mm silver coated SiC die onto the copper paste and conduct die bonding at room temperature for 10 sec at 5-8 kg. Finally, the copper paste is sintered at 260° C. for 10 mins at 20 MPa under nitrogen atmosphere.

Table 3 below tabulates the mechanical properties of the comparative example copper paste.

TABLE 3

| | Shear strength | Shear strength | Shear strength |
|---|---|---|---|
| Sample | Average (MPa) | Maximum (MPa) | Minimum (MPa) |
| CuP-F84 | 25.8 | 26.0 | 25.7 |

### Example 3: Different Microelectronics Surface Finishing

To synthesize the copper paste, mix the copper nanoparticles (synthesized with procedures as elaborated in Example 1 above), plate-shaped copper metal particles in size range of 0.8-5 μm, triethanolamine. ethylene glycol and PEG200 in 20-40 wt %, 10-40 wt %, 3-10 wt %, 5-10 wt % and 3-5 wt % respectively to obtain the copper paste.

For sintering, first clean the copper AMB substrate in 2% citric acid for 5-10 sec, wash with deionized water and ethanol, and dry a low temperature. Then, the copper paste is applied onto the copper AMB substrate by stencil printing. Place the copper AMB substrate in oven at 120° C. for 10 mins under air as a pre-curing process. Then, place the 3 mm*3 mm silver-coated SiC, 3 mm*3 mm gold-coated SiC die pr 3 mm*3 mm copper onto the copper paste and conduct die bonding at room temperature for 10 sec at 5-8 kg. Finally, the copper paste is sintered at 260° C. for 10 mins at 20 MPa under nitrogen atmosphere.

Table 4 below tabulates the respective mechanical properties post-sintering with the different microelectronics surface finishing.

TABLE 4

| | | Shear | Shear | Shear |
|---|---|---|---|---|
| | Microelectronics | strength | strength | strength |
| | surface | Average | Maximum | Minimum |
| Sample | finishing | (MPa) | (MPa) | (MPa) |
| CuP-F162 | Silver finish | 60.95 | 74.74 | >52.51 |
| | Gold finish | >82.0 | 109.8 | >79.4 |
| | Copper | 89.81 | 100.49 | 78.25 |

(Note: “>” indicates die failure.)

### Example 4: Different Sintering Pressures

To synthesize the copper paste, mix the copper nanoparticles (synthesized with procedures as elaborated in Example 1 above), plate-shaped copper metal particles in size range of 0.8-5 μm, triethanolamine. ethylene glycol and PEG200 in 20-40 wt %, 10-40 wt %, 3-10 wt %, 5-10 wt % and 3-5 wt % respectively to obtain the copper paste.

For sintering, first clean the copper AMB substrate in 2% citric acid for 5-10 sec, wash with deionized water and ethanol, and dry a low temperature. Then, the copper paste is applied onto the copper AMB substrate by stencil printing. Place the copper AMB substrate in oven at 120° C. for 10 mins under air as a pre-curing process. Then, place the 3 mm*3 mm silver- or gold-coated SiC die onto the copper paste and conduct die bonding at room temperature for 10 sec at 5-8 kg. Finally, the copper paste is sintered at 260° C. for 10 mins at different pressures under nitrogen atmosphere.

Table 5 below tabulates the respective mechanical properties after sintering under different sintering pressures.

TABLE 5

| | | Shear | Shear | Shear |
|---|---|---|---|---|
| | Sintering | strength | strength | strength |
| | pressure | Average | Maximum | Minimum |
| Sample | (MPa) | (MPa) | (MPa) | (MPa) |
| CuP-F162 | 10 | 53.5 | 62.0 | 48.8 |
| | 15 | 49.3 | 54.3 | 40.2 |
| | 20 | 63.2 | 64.9 | 61.4 |
| | 25 | 70.4 | 71.6 | 68.9 |

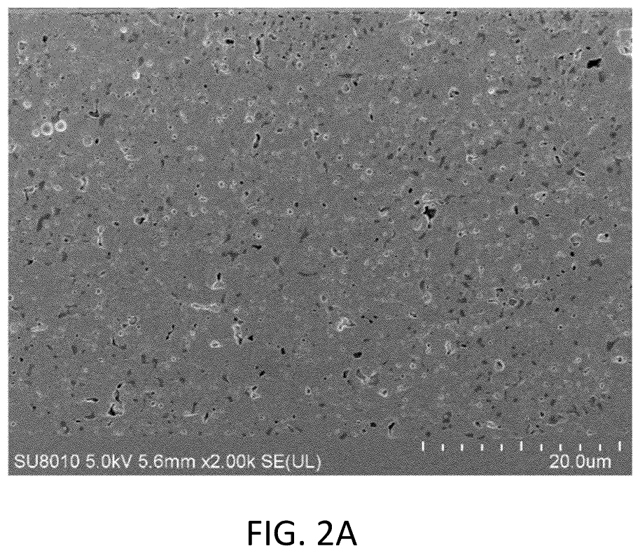

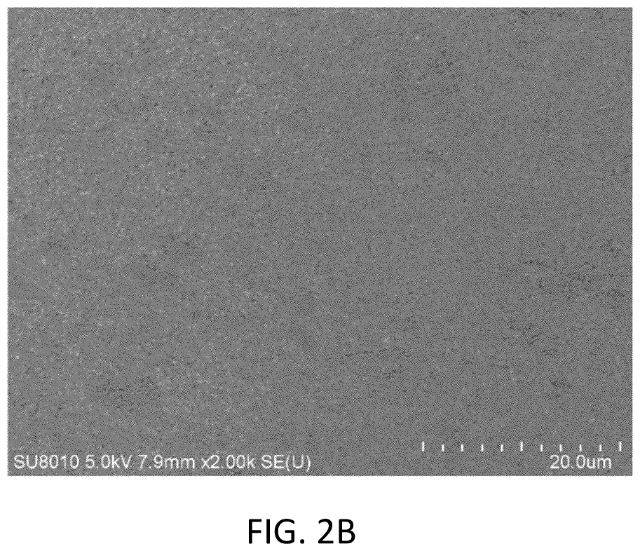

Refer to FIG. 2A, which is a SEM image of the sample synthesized as above under a sintering pressure of 20 MPa, the porosity after sintering is no higher than 10%.

### Example 5: Pressureless Sintering

To synthesize the copper paste, mix the copper nanoparticles (synthesized with procedures as elaborated in Example 1 above), plate-shaped copper metal particles in size range of 0.8-5 μm, triethanolamine. ethylene glycol and diethylene glycol in 60-80 wt %, 10-30 wt %, 3-10 wt %, 3-10 wt % and 3-5 wt % respectively to obtain the copper paste.

For sintering, first clean the copper AMB substrate in 2% citric acid for 5-10 sec, wash with deionized water and ethanol, and dry in a low temperature. Then, the copper paste is applied onto the copper AMB substrate by stencil printing. Then, place the 3 mm*3 mm gold-coated SiC die onto the copper paste and sinter the copper paste at 260° C. for 90 mins under nitrogen atmosphere.

Table 6 below tabulates the mechanical properties after sintering without applying additional pressure.

TABLE 6

| | Shear strength | Shear strength | Shear strength |
|---|---|---|---|
| | Average | Maximum | Minimum |
| Sample | (MPa) | (MPa) | (MPa) |
| CuP-L333 | 50.9 | 56.1 | 49.3 |

FIG. 2B provides the SEM image of the pressureless-sintered copper paste after sintering. Similar to the copper paste after pressure-assisted sintering as shown in Example 4 above, the porosity of this copper paste post-sintering is also lower than 10%.

### Example 6: Pressureless Sintering (II)

To synthesize the copper paste, mix the copper nanoparticles (synthesized with procedures as elaborated in Example 1 above), plate-shaped copper metal particles in size range of 0.8-5 μm, triethanolamine. ethylene glycol, diethylene glycol and 3-glycidoxypropyltrimethoxysilane in 70-80 wt %, 10-20 wt %, 3-10 wt %, 3-10 wt %, 3-5 wt % and 0.5-2 wt % respectively to obtain the copper paste.

For sintering, first clean the copper AMB substrate in 2% citric acid for 5-10 sec, wash with deionized water and ethanol, and dry in a low temperature. Then, the copper paste is applied onto the copper AMB substrate by stencil printing. Then, place the 3 mm*3 mm gold-coated SiC die onto the copper paste and sinter the copper paste at 260° C. for 30 mins under nitrogen atmosphere.

Table 7 below tabulates the mechanical properties after sintering without applying additional pressure.

TABLE 7

| | Shear | Shear | Shear |
|---|---|---|---|
| | strength | strength | strength |
| | Average | Maximum | Minimum |
| Sample | (MPa) | (MPa) | (MPa) |
| CuP-L346A | 34.278 | 38.373 | 30.183 |

### Example 7: Pressureless Sintering-Different Microelectronics Surface Finishing

To synthesize the copper paste, mix the copper nanoparticles (synthesized with procedures as elaborated in Example 1 above), plate-shaped copper metal particles in size range of 0.8-5 μm, triethanolamine. ethylene glycol and diethylene glycol in 70-80 wt %, 10-20 wt %, 3-10 wt %, 3-10 wt %, and 1-3 wt % respectively to obtain the copper paste.

For sintering, first clean the copper AMB substrate in 2% citric acid for 5-10 sec, wash with deionized water and ethanol, and dry in a low temperature. Then, the copper paste is applied onto the copper AMB substrate by stencil printing. Then, place the 3 mm*3 mm gold-coated or silver-coated SiC die or 5 mm*5 mm copper block onto the copper paste and sinter the copper paste at 260° C. for 90 mins under nitrogen atmosphere.

Table 8 below tabulates the mechanical properties post-sintering with different microelectronics surface finishing without applying additional pressure.

TABLE 8

| | | Shear | Shear | Shear |
|---|---|---|---|---|
| | Microelectronics | strength | strength | strength |
| | surface | Average | Maximum | Minimum |
| Sample | finishing | (MPa) | (MPa) | (MPa) |
| CuP-L381 | Silver finish | 30.064 | 36.271 | 24.709 |
| | Gold finish | 45.166 | 59.969 | 37.208 |
| | Copper block | >39.646 | >39.650 | >39.641 |

(Note: “>” indicates that the limit of the die shear strength tester is exceeded.)

### Example 8: Pressureless Sintering-Different Sintering Time

To synthesize the copper paste, mix the copper nanoparticles (synthesized with procedures as elaborated in Example 1 above), plate-shaped copper metal particles in size range of 0.8-5 μm, glycerol, triethanolamine and ethylene glycol in 70-80 wt %, 10-20 wt %, 3-10 wt %, 3-5 wt %, and 3-5 wt % respectively to obtain the copper paste.

For sintering, first clean the copper AMB substrate in 2% citric acid for 5-10 sec, wash with deionized water and ethanol, and dry in a low temperature. Then, the copper paste is applied onto the copper AMB substrate by stencil printing. Then, place the 3 mm*3 mm gold-coated SiC die onto the copper paste and sinter the copper paste at 260° C. for 60/90 mins under nitrogen atmosphere.

Table 9 below tabulates the mechanical properties post-sintering with different sintering time.

TABLE 9

| | | Shear | Shear | Shear |
|---|---|---|---|---|
| | Sintering | strength | strength | strength |
| | time | Average | Maximum | Minimum |
| Sample | (minutes) | (MPa) | (MPa) | (MPa) |
| CuP-L381 | 60 | 61.203 | 66.151 | 52.15 |
| | 90 | 48.955 | 64.030 | 30.50 |

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within 30 μm, within 20 μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit, and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments were chosen and described in order to best explain the principles of the invention and its practical application, thereby enabling others skilled in the art to understand the invention for various embodiments and with various modifications that are suited to the particular use contemplated.

1. An oxidation-resistant copper-based microelectronic joining paste comprising:
10-60% copper metal particles;
30-80% copper nanoparticles;
10-20 wt % solvents;
0.1-5 wt % additives;
wherein the copper metal particles include flake-shaped copper particles, spherical-shaped copper particles, plate-shaped copper particles, or a combination thereof;
wherein the copper nanoparticles are subdivided into a first group and a second group, the first group comprises copper nanoparticles having particle sizes in a range of 10 nm to 80 nm, and the second group comprises copper nanoparticles having particle sizes in a range of 100 nm to 200 nm; and
wherein the solvent comprises both amino and hydroxyl functional groups as anti-agglomeration agent and reducing agent for preventing oxidation of copper nanoparticles.

2. The oxidation-resistant copper-based microelectronic joining paste of claim 1, wherein the copper metal particles have particle sizes in a range of 0.3 μm to 10 μm.

3. The oxidation-resistant copper-based microelectronic joining paste of claim 2, wherein the copper metal particles are copper metal flakes having an aspect ratio of 2 or greater.

4. The oxidation-resistant copper-based microelectronic joining paste of claim 1, wherein the copper metal particle sizes are in a range of 1 μm to 3 μm.

5. The oxidation-resistant copper-based microelectronic joining paste of claim 1, wherein the copper metal particles have crystallite sizes in a range of 90 nm-130 nm.

6. The oxidation-resistant copper-based microelectronic joining paste of claim 1, wherein the first group of copper nanoparticles have crystallite sizes in a range of 15 nm to 40 nm, and the second group of copper nanoparticles have crystallite sizes in a range of 90 nm to 130 nm.

7. The oxidation-resistant copper-based microelectronic joining paste of claim 1, wherein the solvent is selected from the group comprising ethylene glycol, diethylene glycol, triethylene glycol, tetraethylene glycol, 1,3-butylene glycol, dipropylene glycol methyl ether acetate, dipropylene glycol monobutyl ether, dipropylene glycol, diethylene glycol monobutyl ether acetate, triacetin, terpineol, triethanolamine, monoethanolamine, monoisopropanolamine, 2-amino-2-methyl-1-propanol, diglycolamine, diethanolamine, N-methylethanolamine, diisopropanolamine, 2-(tert-butylamino) ethanol, methyldiethanolamine, N-butyldiethanolamine, dimethylethanolamine, triisopropanolamine, diethylethanolamine, or combinations thereof.

8. The oxidation-resistant copper-based microelectronic joining paste of claim 1, wherein the additive is selected from the group comprising polyether modified dimethylpolysiloxane copolymer, a polyamide-based rheology modifier, or a modified urea-based rheology modifier, hexanoic acid, citric acid, malonic acid, ascorbic acid, 3-glycidoxypropyltrimethoxysilane, or combinations thereof.

9. A two-step sintering method using the oxidation-resistant copper-based microelectronic joining paste of claim 1, comprising:
applying the paste of claim 1 to a substrate;
placing a microelectronic component at least partially on the paste applied to the substrate; and
heating to a temperature in a range of 250° C. to 280° C. under nitrogen atmosphere to sinter the copper metal particles with copper nanoparticles paste and bond the microelectronic component to the substrate.

10. The two-step sintering method of claim 9, wherein the substrate is selected from copper finishing, silver finishing, gold finishing, platinum finishing, or nickel finishing.

11. The two-step sintering method of claim 9, wherein the microelectronic component is selected from copper finishing, silver finishing or gold finishing.

12. The two-step sintering method of claim 9, wherein the bondline thickness between the copper metal particles and the copper nanoparticles is 20-50 μm.

13. The two-step sintering method of claim 9, wherein the porosity of the paste after sintering is less than 10%.

14. The two-step sintering method of claim 9, wherein the sintering is conducted under a pressure of 1 atm for a time period of no less than 60 minutes.

15. The two-step sintering method of claim 14, wherein the bond has an average shear strength of at least 30 MPa.

16. The two-step sintering method of claim 9, wherein the sintering is conducted under a pressure in a range of 10 MPa to 25 MPa for a time period of approximately 10 minutes.

17. The two-step sintering method of claim 16, wherein the bond has an average shear strength of at least 50 MPa.
